(19) United States
(12) Patent Application Publication
(10) Pub. No.: US 2025/0279309 A1
(43) Pub. Date: Sep. 4, 2025

(54) ELECRO-STATIC CHUCK AND SUBSTRATE PROCESSING APPARATUS INCLUDING THE SAME

(71) Applicant: SAMSUNG ELECTRONICS CO., LTD., Suwon-si (KR)

(72) Inventors: Hakyoung Kim, Suwon-si (KR); Yongwoo Kim, Suwon-si (KR); Wonsub Hwang, Suwon-si (KR); Hansol Kim, Suwon-si (KR); Minnhoo Choi, Suwon-si (KR)

(21) Appl. No.: 18/909,343

(22) Filed: Oct. 8, 2024

(30) Foreign Application Priority Data
Feb. 29, 2024 (KR) 10-2024-0030110

(51) Int. Cl. H01L 21/683; H01J 37/32

(52) U.S. Cl. CPC H01L 21/6833; H01J 37/32715; H01J 2237/2007

(57) ABSTRACT

An electro-static chuck includes a chuck plate configured to seat a substrate, an insulating pillar on the outside of the chuck plate, a first ring surrounding a side portion of the chuck plate on the insulating pillar, a second ring covering at least a portion of an upper portion of the first ring, and a heating plate configured to discharge heat from a lower portion of the chuck plate to heat the substrate, wherein the second ring is arranged such that an overlap of a first region of the substrate affected by the heating plate and a second region of the substrate affected by the second ring is minimized.

### CROSS-REFERENCE TO RELATED APPLICATION

This application claims priority to Korean Patent Application No. 10-2024-0030110, filed on Feb. 29, 2024, in the Korean Intellectual Property Office, the disclosure of which is incorporated by reference herein in its entirety.

### BACKGROUND

An electro-static chuck may include a heating plate for heating a substrate, and a ring surrounding the substrate. The ring may determine the shape of plasma formed in a chamber of a substrate processing apparatus. Based on the position of the ring, the plasma shape may be changed.

### SUMMARY

In general, in some aspects, the present disclosure is directed toward an electro-static chuck having improved reliability and a substrate processing apparatus including the electro-static chuck.

According to some implementations, the present disclosure is directed to an electro-static chuck that includes a chuck plate configured to seat a substrate, an insulating pillar on the outside of the chuck plate, a first ring surrounding a side portion of the chuck plate on the insulating pillar, a second ring covering at least a portion of an upper portion of the first ring, and a heating plate configured to discharge heat from a lower portion of the chuck plate to heat the substrate, wherein the second ring is arranged such that an overlap of a first region of the substrate affected by the heating plate and a second region of the substrate affected by the second ring is minimized.

According to some implementations, the present disclosure is directed to an electro-static chuck that includes a chuck plate configured to seat a substrate, an insulating pillar which is formed on the outside of the chuck plate and has a pin hole, a first ring surrounding a side portion of the chuck plate on the insulating pillar, a second ring covering at least a portion of an upper portion of the first ring, a driving pin configured to be movable in a vertical direction from the pin hole of the insulating pillar and overlapping at least a portion of the second ring in the vertical direction, and a heating plate configured to discharge heat from a lower portion of the chuck plate to heat the substrate, wherein the second ring is arranged such that an overlap of a first region of the substrate affected by the heating plate and a second region of the substrate affected by the second ring is minimized.

According to some implementations, the present disclosure is directed to an electro-static chuck that includes a chuck plate configured to seat a substrate, an insulating pillar on the outside of the chuck plate, a first ring surrounding a side portion of the chuck plate on the insulating pillar, a second ring covering at least a portion of an upper portion of the first ring, and a heating plate configured to discharge heat from a lower portion of the chuck plate to heat the substrate, wherein the chuck plate includes a first portion on which the substrate is seated and a second portion extending from a lower portion of the first portion to the outside of the first portion, and the second ring is spaced apart from the first portion in a horizontal direction by about 3.5 mm or more.

### BRIEF DESCRIPTION OF THE DRAWINGS

Example implementations will be more clearly understood from the following detailed description, taken in conjunction with the accompanying drawings.

FIG. 1 is a cross-sectional view showing an example of a electro-static chuck according to some implementations.

FIG. 2 is an enlarged cross-sectional view of an example of a side portion of the electro-static chuck of FIG. 1 according to some implementations.

FIG. 3 is a plan view illustrating an example of a region of a substrate according to some implementations

FIG. 4 is a plan view illustrating an example of a region of a substrate according to some implementations.

FIG. 5 is a plan view illustrating an example of a region of a substrate according to some implementations

FIG. 6 is a cross-sectional view showing an example of an electro-static chuck according to some implementations.

FIG. 7 is an enlarged cross-sectional view of an example of a side portion of the electro-static chuck of FIG. 6 according to some implementations.

FIG. 8 is an enlarged cross-sectional view of an example of a side portion of the electro-static chuck of FIG. 6 according to some implementations.

FIG. 9 is a cross-sectional view illustrating an example of a substrate processing apparatus according to some implementations.

### DETAILED DESCRIPTION

Hereinafter, example implementations will be explained in detail with reference to the accompanying drawings. The same reference numerals are used for the same elements in the drawings, and redundant descriptions thereof are omitted.

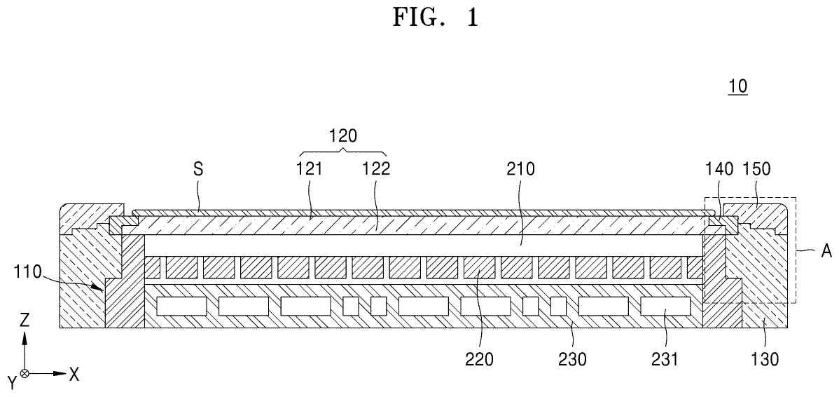

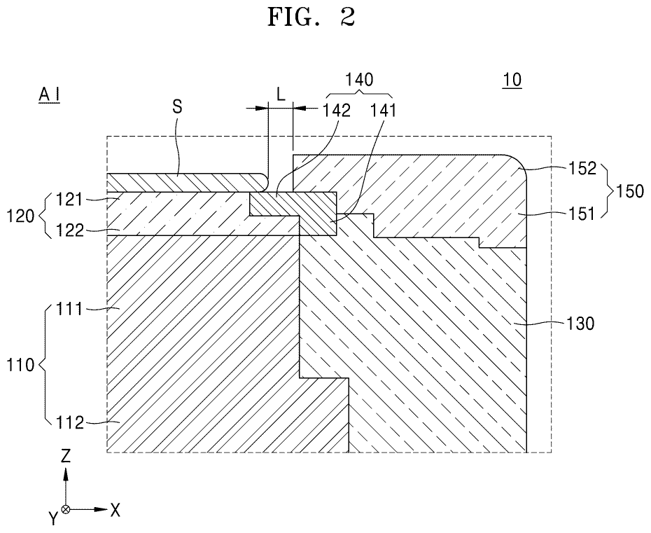

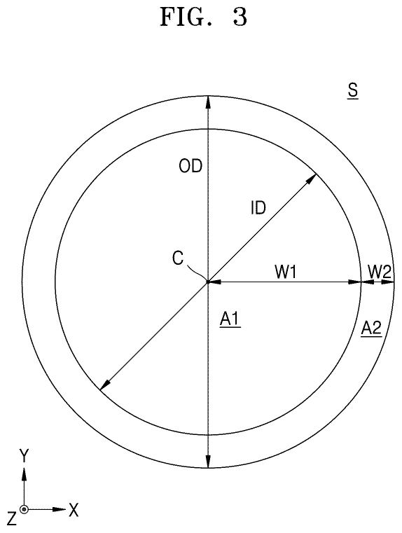

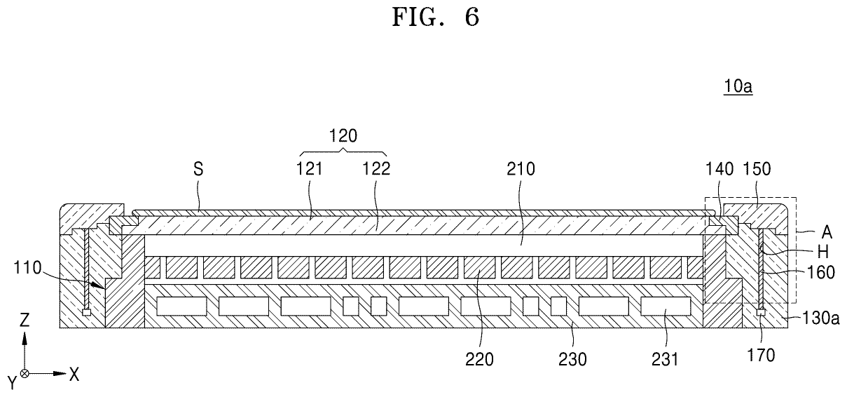

FIG. 1 is a cross-sectional view showing an example of an electro-static chuck according to some implementations, and FIG. 2 is an enlarged cross-sectional view of an example of a side portion of the electro-static chuck of FIG. 1 according to some implementations. FIG. 3 is a plan view illustrating an example of a region of a substrate according to some implementations. FIG. 2 illustrates a side portion A_1 of an electro-static chuck 10 from which a driving pin 160 (of FIG. 6) is omitted.

In FIGS. 1 to 3, the electro-static chuck 10 may include a body portion 110, a chuck plate 120, an insulating pillar 130, a first ring 140, and a second ring 150. In addition, the electro-static chuck 10 may further include an electro-static plate 210, a heating plate 220, and a cooling plate 230.

In some implementations, the body portion 110 may be a pedestal having a cylindrical shape. The body portion 110 may accommodate the electro-static plate 210, the heating plate 220, the cooling plate 230, and the like therein.

The body portion 110 may include a first portion 111 on which the chuck plate 120 is seated and a second portion 112 extending from a lower portion of the first portion 111 to the outside of the first portion 111. When the body portion 110 is viewed from top to bottom, the top surface of the first portion 111 and the top surface of the second portion 112 may be partially exposed.

In some implementations, the chuck plate 120 may be on the body portion 110. The chuck plate 120 may be a plate on which a substrate S is seated. For example, the substrate S seated on the chuck plate 120 may be a wafer on which semiconductor devices are formed. The chuck plate 120 may include a non-conductive material having little deformation by heat for resistance by high-temperature plasma.

Here, the diameter of the substrate S may be about 300 mm, but is not limited thereto. The diameter of the substrate S may be, for example, about 150 mm, about 200 mm, or about 450 mm, or more. Hereinafter, a case in which the diameter of the substrate S is about 300 mm will be described as an example.

The chuck plate 120 may include a first portion 121 on which the substrate S is seated and a second portion 122 extending from a lower portion of the first portion 121 to the outside of the first portion 121. When the chuck plate 120 is viewed from top to bottom, the top surface of the first portion 121 and the top surface of the second portion 122 may be partially exposed.

In some implementations, the insulating pillar 130 may be at the outside the chuck plate 120. More specifically, the insulating pillar 130 may surround the body portion 110 from the outside of the chuck plate 120. In addition, the insulating pillar 130 may be a pillar including an insulating material.

The first ring 140 may be a ring surrounding a side portion of the chuck plate 120 on the insulating pillar 130. More specifically, the first ring 140 may surround the side surface of the first portion 121 and the top surface of the second portion 122 of the chuck plate 120 on the insulating pillar 130. Since the first ring 140 surrounds the side portion of the chuck plate 120, the risk of damage to the chuck plate 120 by plasma in a substrate processing process may be reduced. The first ring 140 is a ring for protecting the chuck plate 120 and may be referred to as a protection ring and/or an insert ring. In addition, when the substrate S is seated on the chuck plate 120, a part of the first ring 140 may overlap a part of the edge of the substrate S in a vertical direction (Z direction).

In the present disclosure, a direction parallel to the main surface of the substrate S may be defined as a horizontal direction (X direction and/or Y direction), and a direction perpendicular to the horizontal direction (X direction and/or Y direction) may be defined as a vertical direction (Z direction).

The first ring 140 may include a support portion 141 and a protection portion 142. In some implementations, the support portion 141 may be a portion of the first ring 140 seated on the insulating pillar 130. The support portion 141 may be in contact with the insulating pillar 130.

In some implementations, the protection portion 142 may be a portion of the first ring 140 extending in the horizontal direction (X and/or Y directions) from the inside of the support portion 141 and surrounding the side portion of the chuck plate 120. More specifically, the protection portion 142 may extend in the horizontal direction (X and/or Y directions) from the inside of the support portion 141 to surround the side surface of the first portion 121 and the top surface of the second portion 122 of the chuck plate 120. The protection portion 142 may be in contact with the side portion of the chuck plate 120.

The second ring 150 may be seated on the insulating pillar 130 and may partially cover the upper portion of the insulating pillar 130 and the upper portion of the first ring 140. The second ring 150 may prevent etching of the first ring 140 by plasma in a substrate processing process.

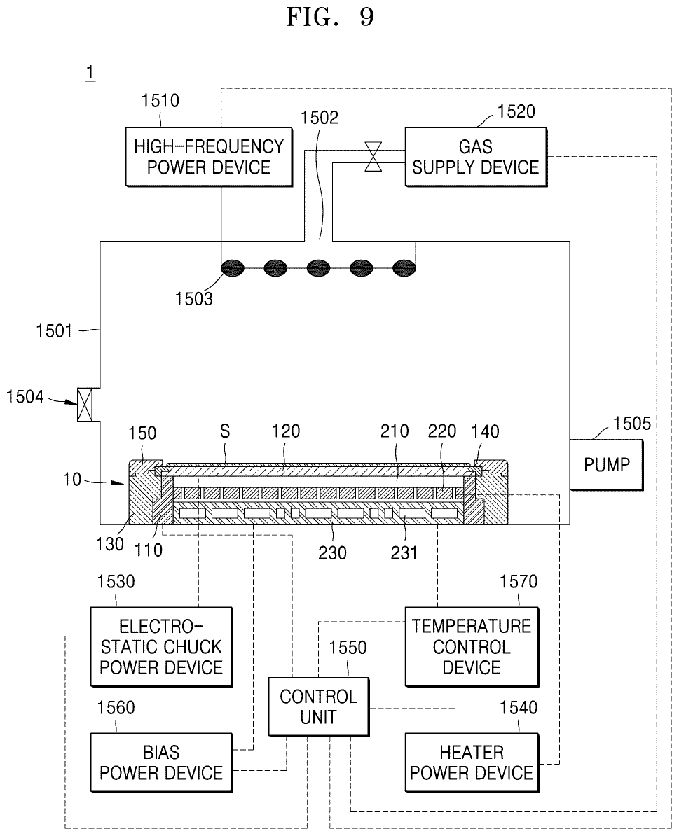

The second ring 150 may be a ring that affects a shape of plasma formed in a substrate processing process. For example, when the shape of the second ring 150 or the separation distance in the vertical direction (Z direction) of the second ring 150 and the insulating pillar 130 changes, the shape of plasma formed in the substrate processing process may also change. For example, when the shape of the second ring 150 or the separation distance between the second ring 150 and the insulating pillar 130 changes, the shape of the plasma inside a process chamber 1501 of a substrate processing apparatus 1 (FIG. 9) may change. The second ring 150 may be referred to as a focus ring and/or an edge ring. In addition, the second ring 150 may be a ring including materials, such as quartz, silicon, silicon carbide, silicon oxide, aluminum oxide, etc.

The second ring 150 may include a contact portion 151 and a cover portion 152. The contact portion 151 may be a portion of the second ring 150 surrounding a side portion of the first ring 140 on the insulating pillar 130. The contact portion 151 may be in contact with each of the insulating pillar 130 and the first ring 140.

The cover portion 152 may be a portion of the second ring 150 that extends in the horizontal direction (X and/or Y directions) on the contact portion 151 and partially covers the upper portion of the first ring 140. More specifically, the cover portion 152 may extend in the horizontal direction (X direction and/or Y direction) from the upper portion of the contact portion 151 and may partially cover the first ring 140.

The top surface of the second ring 150 may be positioned at a vertical level higher than the top surface of the chuck plate 120. The top surface of the cover portion 152 may be positioned at a vertical level higher than the top surface of the chuck plate 120. In addition, the top surface of the second ring 150 may be located at a vertical level higher than the top surface of a substrate S loaded on the chuck plate 120.

Although FIGS. 1 and 2 show that the electro-static chuck 10 includes two rings, some implementations are not limited thereto. For example, the electro-static chuck 10 may include one ring or three or more rings.

In some implementations, the electro-static plate 210 may be a plate that generates an electro-static force under the chuck plate 120. The electro-static plate 210 may be electrically connected to an electro-static chuck power device (1530 of FIG. 9) to be described below. An electro-static force may be generated between the electro-static plate 210 and the substrate S by the power applied from the electro-static chuck power device 1530, for example, a direct current voltage. The substrate S may be firmly seated on the chuck plate 120 by the electro-static force.

In some implementations, the heating plate 220 may be a plate configured to dissipate heat to heat the substrate S on the chuck plate 120. The heating plate 220 may be electrically connected to a heater power device (1550 of FIG. 9) to be described later. The heating plate 220 may include a plurality of heating elements. For example, the heating plate 220 may include at least one of a thermoelectric element, a resistance heater, and an inductance heater. The plurality of heating elements may be individually controlled for local temperature control of the substrate S on the chuck plate 120.

In some implementations, the cooling plate 230 may be a plate configured to cool a substrate on the chuck plate 120 or a plurality of electronic devices included in the electro-static chuck 10. The cooling plate 230 may be electrically connected to a temperature control device (1570 of FIG. 9) to be described later. The cooling plate 230 may include a cooling water channel 231 through which at least one cooling water among water, ethylene glycol, and silicone oil flows.

The substrate S may include a plurality of regions. For example, the substrate S may include a first region A1 and a second region A2. When viewed in a plan view, the second region A2 may surround the first region A1. For example, the first region A1 may refer to the region of the substrate S affected (i.e., heated) by the heating plate 220, and the second region A2 may refer to the region of the substrate S affected by the second ring 150. When viewed in a plan view, the first region A1 may be arranged adjacent to the center C of the substrate S, and the second region A2 may be arranged adjacent to the edge of the substrate S.

When viewed in a plan view, the first region A1 may have a circular shape, and the second region A2 may have a ring shape. However, some implementations are not limited thereto, and the shape of each of the first region A1 and/or the second region A2 may be variously modified.

Hereinafter, a case in which the first region A1 has a circular shape and the second region A2 has a ring shape will be described as an example. Accordingly, the first region A1 may have a radius, and the second region A2 may have an inner diameter ID and an outer diameter OD.

The first region A1 may have a first width W1 in the radial direction of the substrate S at the center C of the substrate S, and the second region A2 may have a second width W2 in the radial direction of the substrate S. The second width W2 may be a thickness of the second region A2 extending in a radial direction of the substrate S of the second region A2. That is, the second width W2 may be a thickness of a ring-shaped region.

For example, the first width W1 may be about 120 mm to about 147 mm, and the second width W2 may be about 3 mm to about 15 mm. For example, the center of the first region A1 and the center C of the substrate S may coincide with each other. In some implementations, the center of the first region A1 and the center C of the substrate S may be spaced apart from each other.

For efficient control of the substrate S, the second ring 150 may be arranged so that an overlap between the first region A1 and the second region A2 is minimized. When the first region A1 and the second region A2 overlap, the frequency of occurrence of discontinuities of process parameters increases, process distribution increases in plasma substrate processing, and thus the reliability of the plasma processing process may decrease. Accordingly, when the overlap between the first region A1 and the second region A2 is minimized, the reliability of the plasma substrate processing process may increase.

For example, the second ring 150 may be arranged so that the first region A1 and the second region A2 do not overlap each other. For example, the heating plate 220 and the second ring 150 may be arranged so that the first region A1 and the second region A2 do not overlap each other and the sum of the plane area of the first region A1 and the plane area of the second region A2 are the same as the plane area of the substrate S. That is, the first region A1 and the second region A2 may be in contact with each other. That is, the sum of the first width W1 and the second width W2 may be the same as the radius of the substrate S.

For example, the second ring 150 may be arranged with a horizontal distance L from the substrate S in the horizontal direction (X and/or Y directions). As the horizontal distance L between the second ring 150 and the substrate S increases, the plane area of the second region A2 decreases, and the horizontal separation distance between the second region A2 and the center C of the substrate S may increase. In more detail, as the horizontal distance L between the second ring 150 and the substrate S increases, the inner diameter ID and/or the outer diameter OD of the second region A2 may increase. In some implementations, the outer diameter OD of the second region A2 may be the same as the radius of the substrate S. In some implementations, the outer diameter OD of the second region A2 may be less than the radius of the substrate S. That is, as the horizontal distance L between the second ring 150 and the substrate S increases, the overlapping region of the first region A1 and the second region A2 may decrease.

For example, the horizontal distance L may be greater than or equal to about 3.5 mm. The horizontal distance L may be variously modified by the radius of the substrate S, the arrangement of the heating plate 220, and/or the shape of the body portion 110. For example, the second ring 150 may be spaced apart from the first portion 121 of the chuck plate 120 by about 3.5 mm or more in the horizontal direction (X and/or Y directions).

In general, an electro-static chuck may include a second ring is arranged without considering the overlap between the first region and the second region of the substrate. Accordingly, the overlapping region of the first region and the second region on the substrate was wide. A distribution inflection point occurred in a region where the first region and the second region overlap, and the reliability of the plasma processing process was low.

In the electro-static chuck 10, the second ring 150 may be arranged so that an overlap between the first region A1 and the second region A2 of the substrate S is minimized. Accordingly, the region in which the distribution inflection point on the substrate S occurs may be minimized, and the reliability of the plasma processing process may be increased.

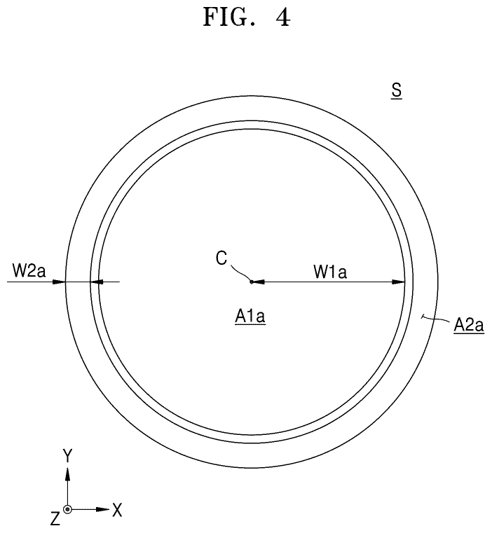

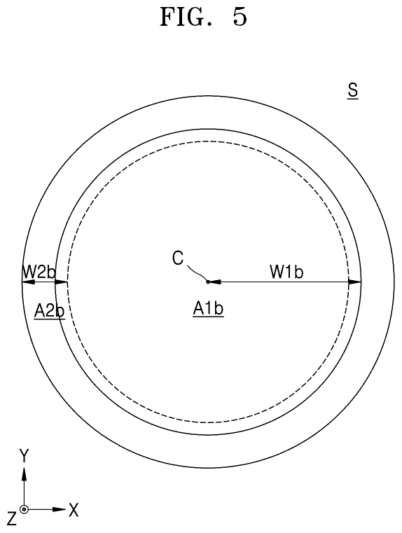

FIGS. 4 and 5 are plan views illustrating an example of a region of a substrate according to some implementations. FIG. 4 illustrates a case where a first region Ala and a second region A2a do not overlap each other, and the sum of the plane area of the first region Ala and the plane area of the second region A2a is less than the plane area of the substrate S. FIG. 5 illustrates a case where at least a portion of each of the first region Alb and the second region A2b overlaps. Description will be made with reference to FIGS. 4 and 5 together with FIGS. 1 to 3.

In FIGS. 4 and 5, the first region Ala of the substrate S of FIG. 4 may have a first width W1a, and the second region A2a thereof may have a second width W2a. In addition, the first region Alb of the substrate S of FIG. 5 may have a first width W1b, and the second region A2b may have a second width W2b. The arrangement positions of the second ring 150 and/or the heating plate 220 may be adjusted so that the first widths W1a and W1b and/or the second widths W2a and W2b may be modified.

In some implementations, each of the first width W1a of FIG. 4 and the first width W1b of FIG. 5 may be the same as the first width W1 of FIG. 3. In some implementations, the first width W1a of FIG. 4 and/or the first width W1b of FIG. 5 may be different from the first width W1 of FIG. 3. Also, in some implementations, each of the second width W2a of FIG. 4 and the second width W2b of FIG. 5 may be different from the second width W2 of FIG. 3.

The sum of the plane area of the first region Ala of FIG. 4 and the plane area of the second region A2a may be less than the plane area of the substrate S. The first region Ala and the second region A2a of FIG. 4 may be spaced apart from each other in the horizontal direction (X direction and/or Y direction). In addition, the sum of the plane area of the first region Alb and the plane area of the second region A2b of FIG. 5 may be greater than the plane area of the substrate S. That is, at least a portion of each of the first region Alb and the second region A2b of FIG. 5 may overlap each other.

That is, the sum of the first width W1a and the second width W2a of FIG. 4 may be less than the radius of the substrate S. In addition, the sum of the first width W1b and the second width W2b of FIG. 5 may be greater than the radius of the substrate S.

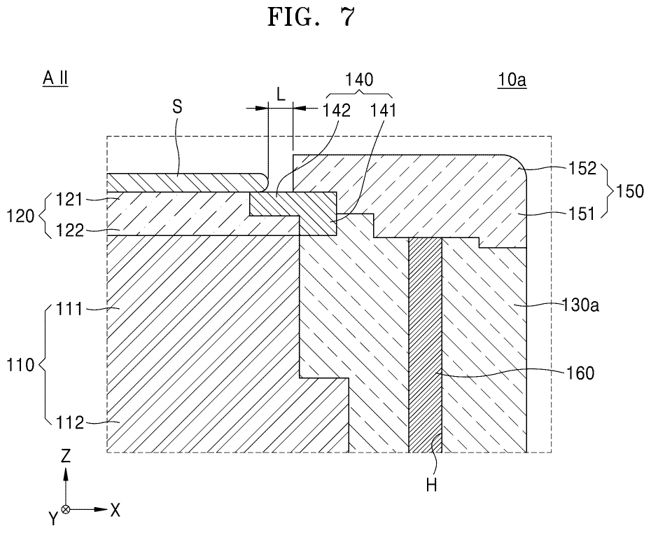

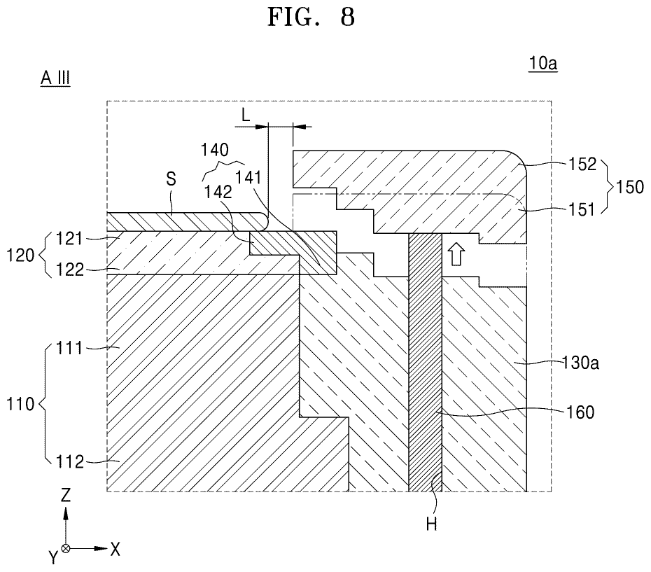

FIG. 6 is a cross-sectional view showing an example of an electro-static chuck according to some implementations, and FIGS. 7 and 8 are enlarged cross-sectional views of an example of a side portion of the electro-static chuck of FIG. 6 according to some implementations. FIG. 7 shows a side portion A_II of the electro-static chuck 10a in which a driving pin 160 is in a first state, and FIG. 8 shows a side portion A_III of the electro-static chuck 10a in which the driving pin 160 is in a second state.

In FIGS. 6 to 8, the electro-static chuck 10a may include the body portion 110, the chuck plate 120, the insulating pillar 130a, the first ring 140, the second ring 150, a driving pin 160, and a power source 170. In addition, the electro-static chuck 10a may further include the electro-static plate 210, the heating plate 220, and the cooling plate 230. The electro-static chuck 10a of FIGS. 6 to 8 may further include the driving pin 160 and the power source 170 in the electro-static chuck 10 of FIGS. 1 and 2.

The insulating pillar 130a may have a pin hole H formed therein. The pin hole H may provide a space in which the driving pin 160 may move in the vertical direction (Z direction). The pin hole H may overlap at least a portion of the second ring 150 in the vertical direction (Z direction). In some implementations, the pin hole H may overlap at least a portion of each of the first ring 140 and the second ring 150 in the vertical direction (Z direction).

The second ring 150 may be driven in the vertical direction (Z direction) by the driving pin 160. In the substrate processing process, the second ring 150 may move in the vertical direction (Z direction) in order to implement the plasma in a previously predicted shape. More specifically, the driving pin 160 may be under the second ring 150, and at least a portion of the second ring 150 may overlap a portion of the driving pin 160 in the vertical direction (Z direction). The second ring 150 may be driven in the vertical direction (Z direction) by an external force transmitted from the driving pin 160 to the second ring 150.

In addition, in some implementations, the second ring 150 may be driven in the vertical direction (Z direction) while the substrate S is seated on the chuck plate 120. The second ring 150 may be moved in the vertical direction (Z direction) in the process of processing the substrate S. The separation distance between the second ring 150 and the insulating pillar 130a in the vertical direction (Z direction) may be controlled by the driving pin 160. Accordingly, the shape of the plasma formed in the substrate processing process may also be controlled by the driving pin 160. For example, when the shape of the plasma in the substrate processing process is different from the shape predicted in advance, the second ring 150 may be driven in the vertical direction (Z direction) by the driving pin 160. Accordingly, in the substrate processing process, plasma may be formed in a previously predicted shape.

In some implementations, the driving pin 160 may be a pin that moves in the vertical direction (Z direction) in the pin hole H of the insulating pillar 130a. More specifically, the driving pin 160 may move in the vertical direction (Z direction) within the pin hole H to drive the second ring 150 in the vertical direction (Z direction).

The driving pin 160 may include a rod-shaped pin extending in the vertical direction (Z direction) in the pin hole H. There may be a plurality of driving pins 160, and the plurality of driving pins 160 may be formed to be symmetrical with respect to the center of the chuck plate 120. For example, there may be three driving pins 160, and the three driving pins 160 may be formed symmetrically with respect to the center of the chuck plate 120.

The driving pin 160 may overlap at least a portion of the second ring 150 in the vertical direction (Z direction). Accordingly, the driving pin 160 may drive the second ring 150 in the vertical direction (Z direction).

The driving pin 160 may be in one of the first state and the second state. The first state of the driving pin 160 may be a state in which the driving pin 160 does not drive the second ring 150 in the vertical direction (Z direction). In the first state, the driving pin 160 may be in contact with the second ring 150. In some implementations, in the first state, the driving pin 160 may be spaced apart from the second ring 150 in the vertical direction (Z direction).

The second state of the driving pin 160 may be a state in which the driving pin 160 moves to drive the second ring 150 in the vertical direction (Z direction). As described above, the driving pin 160 may drive the second ring 150 in the vertical direction (Z direction) to change the shape of plasma formed in the substrate processing process. When the driving pin 160 is in the second state, the second ring 150 may be driven in the vertical direction (Z direction) to be spaced apart from the insulating pillar 130 in the vertical direction (Z direction). When the driving pin 160 is in the second state, the driving pin 160 may not drive the first ring 140 in the vertical direction (Z direction). In some implementations, when the driving pin 160 is in the second state, the driving pin 160 may drive the first ring 140 in the vertical direction (Z direction).

In some implementations, it is not limited to those illustrated in FIGS. 6 to 8, and the electro-static chuck 10a may include three or more rings. In addition, the plurality of rings may overlap at least a portion of the driving pin 160 in the vertical direction (Z direction). Accordingly, when the driving pin 160 moves in the vertical direction (Z direction), at least one of the plurality of rings may be driven in the vertical direction (Z direction).

In some implementations, the power source 170 may be a device that transmits power to the driving pin 160. More specifically, the power source 170 may be a device that transmits power to the driving pin 160 for movement of the driving pin 160 in the vertical direction (Z direction). For example, the power source 170 may include a hydraulic device, a motor, and the like.

The electro-static chuck 10a may further include a control unit for controlling the operations of the components of the electro-static chuck 10a. The control unit may control movement of the driving pin 160 in the vertical direction (Z direction) by controlling the power source 170. That is, the control unit may control movement of the second ring 150 in the vertical direction (Z direction). The control unit may control the movement of the second ring 150 in the vertical direction (Z direction) by controlling the power source 170 to control the plasma on the substrate S.

The control unit may be implemented in hardware, firmware, software, or any combination thereof. For example, the control unit may be a computing device, such as a workstation computer, a desktop computer, a laptop computer, a tablet computer, or the like. For example, the control unit may include memory devices, such as Read Only Memory (ROM) and Random Access Memory (RAM), and a processor configured to perform predetermined operations and algorithms, such as a microprocessor, a central processing unit (CPU), and a graphics processing unit (GPU). In addition, the control unit may include a receiver and a transmitter for receiving and transmitting electrical signals.

FIG. 9 is a cross-sectional view illustrating an example of a substrate processing apparatus according to some implementations. The substrate processing apparatus may be a substrate processing apparatus including at least one of the electro-static chuck 10 and 10a described above. Description will be made with reference to FIG. 9 together with FIGS. 1 to 8.

In FIG. 9, the substrate processing apparatus 1 may include an electro-static chuck 10, a process chamber 1501, a gas supply pipe 1502, a plasma generating device 1503, a gate 1504, a pump 1505, a high-frequency power device 1510, a gas supply device 1520, an electro-static chuck power device 1530, a heater power device 1540, a control unit 1550, a bias power device 1560, a temperature control apparatus 1570, and the like.

In some implementations, the electro-static chuck 10 of the substrate processing apparatus 1 may be a device that fixes the substrate S by electro-static force. Since the technical idea of the electro-static chuck 10 may be substantially the same as those described with reference to FIGS. 1 to 8, detailed descriptions thereof will be omitted.

In some implementations, the process chamber 1501 may provide an inner space for processing the substrate S. The electro-static chuck 10 may be positioned in the inner space of the process chamber 1501. The gas supply pipe 1502 may be connected to the gas supply device 1520. The gas supply pipe 1502 may be configured to inject the process gas provided by the gas supply device 1520 into the process chamber 1501. The processing gas may include an etching gas for etching the substrate S. In addition, the processing gas may include a protection gas for protecting patterns formed on the substrate S.

In some implementations, the gate 1504 may provide a path through which the substrate S may move. For example, the substrate S may move to the outside of the process chamber 1501 through the gate 1504, or may move to the inside of the process chamber 1501 through the gate 1504. The pump 1505 may be configured to adjust an internal pressure of the process chamber 1501. For example, the pump 1505 may increase the pressure by injecting air into the process chamber 1501. In addition, the pump 1505 may discharge air inside the process chamber 1501 to reduce pressure.

In some implementations, the high-frequency power device 1510 may be electrically connected to the plasma generating device 1503. The high-frequency power device 1510 may output high-frequency power suitable for generating plasma and transmit the output high-frequency power to the plasma generating device 1503. The high-frequency power of the high-frequency power device 1510 may be controlled by the control unit 1550.

In some implementations, the electro-static chuck power device 1530 may be electrically connected to the electro-static chuck 10. More specifically, the electro-static chuck power device 1530 may be electrically connected to the electro-static plate 210 of the electro-static chuck 10. An electro-static force may be generated between the electro-static plate 210 and the substrate S by the power applied from the electro-static chuck power device 1530, for example, a direct current voltage. The substrate S may be firmly seated on the chuck plate 120 of the electro-static chuck 10 by the electro-static force.

In some implementations, the heater power device 1540 may be electrically connected to the heating plate 220. The heater power device 1540 may be connected to the control unit 1550, and the heating amount of a plurality of heating elements included in the heating plate 220 may be controlled.

In some implementations, the bias power device 1560 may be connected to a lower portion of the body portion 110. The bias power device 1560 may apply high-frequency power to a lower portion of the body 110. The lower portion of the body portion 110 may serve as an electrode for generating plasma.

In some implementations, the temperature control device 1570 may be connected to the cooling water channel 231 of the cooling plate 230 and the control unit 1550. The temperature control device 1570 may control the temperature of the cooling water flowing through the cooling water channel 231.

In some implementations, the control unit 1550 may be configured to control at least one of the high-frequency power device 1510, the gas supply device 1520, the electro-static chuck power device 1530, the heater power device 1540, the bias power device 1560, and the temperature control device 1570.

In some implementations, the control unit 1550 may be configured to control the power source 170 of the electro-static chuck 10. The power source 170 may be controlled by the control unit 1550 to drive the second ring 150. The electro-static chuck 10 of the embodiments may be in at least one of the first state and the second state described above by the power source 170 controlled by the control unit 1550.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An electro-static chuck comprising:
a chuck plate configured to seat a substrate;
an insulating pillar on an exterior of the chuck plate;
a first ring surrounding a side portion of the chuck plate on the insulating pillar;
a second ring covering at least a portion of an upper portion of the first ring; and
a heating plate configured to transmit heat from a lower portion of the chuck plate to heat the substrate,
wherein the second ring is arranged such that an overlap of a first region of the substrate affected by the heating plate and a second region of the substrate affected by the second ring is minimized.

2. The electro-static chuck of claim 1, wherein, from a plan view, the first region of the substrate and the second region of the substrate are adjacent to each other.

3. The electro-static chuck of claim 1, wherein, from a plan view, the second region of the substrate surrounds the first region of the substrate.

4. The electro-static chuck of claim 1, wherein, from a plan view, the first region of the substrate is placed adjacent to a center of the substrate, and the second region of the substrate is placed adjacent to an edge of the substrate.

5. The electro-static chuck of claim 1, further comprising a body portion including a first portion upon which the chuck plate is seated and a second portion extending from a lower portion of the first portion to an exterior of the first portion,
wherein the heating plate is placed inside the body portion.

6. The electro-static chuck of claim 1, wherein the second ring comprises:
a contact portion surrounding a side portion of the first ring on the insulating pillar; and
a cover portion extending in a horizontal direction and surrounding an upper portion of the first ring on the contact portion.

7. The electro-static chuck of claim 1,
wherein the first region of the substrate has a first width in a radial direction of the substrate from a center of the substrate, and the second region of the substrate has a second width in the radial direction of the substrate,
wherein the first width is within a range of about 120 mm to about 147 mm, and
wherein the second width is within a range of about 3 mm to about 15 mm.

8. The electro-static chuck of claim 1, wherein a horizontal separation distance between the substrate and the second ring is about 3.5 mm or more.

9. An electro-static chuck comprising:
a chuck plate configured to seat a substrate;
an insulating pillar formed on an exterior of the chuck plate, the insulating pillar having a pin hole;
a first ring surrounding a side portion of the chuck plate on the insulating pillar;
a second ring covering at least a portion of an upper portion of the first ring;
a driving pin configured to be movable in a vertical direction withing the pin hole of the insulating pillar and overlapping at least a portion of the second ring in the vertical direction; and
a heating plate configured to transmit heat from a lower portion of the chuck plate to heat the substrate,
wherein the second ring is arranged such that an overlap of a first region of the substrate affected by the heating plate and a second region of the substrate affected by the second ring is minimized.

10. The electro-static chuck of claim 9, wherein the driving pin is configured to drive the second ring in the vertical direction.

11. The electro-static chuck of claim 9, further comprising a power source configured to transmit power to the driving pin.

12. The electro-static chuck of claim 9, wherein the first ring is spaced apart from the driving pin in the vertical direction.

13. The electro-static chuck of claim 9, wherein, from a plan view, the first region has a circular shape and the second region has a ring shape.

14. The electro-static chuck of claim 13, wherein, from a plan view, an outer diameter of the second region is the same as an outer diameter of the substrate.

15. The electro-static chuck of claim 9, wherein a sum of a plane area of the first region and a plane area of the second region is equal to or smaller than a plane area of the substrate.

16. An electro-static chuck comprising:
a chuck plate configured to seat a substrate;
an insulating pillar on an exterior of the chuck plate;
a first ring surrounding a side portion of the chuck plate on the insulating pillar;
a second ring covering at least a portion of an upper portion of the first ring; and
a heating plate configured to transmit heat from a lower portion of the chuck plate to heat the substrate,
wherein the chuck plate includes a first portion on which the substrate is seated and a second portion extending from a lower portion of the first portion to an exterior of the first portion, and
wherein the second ring is spaced apart from the first portion in a horizontal direction by about 3.5 mm or more.

17. The electro-static chuck of claim 16, wherein the insulating pillar further comprises:
a pin hole; and
a driving pin configured to be movable in a vertical direction within the pin hole of the insulating pillar and overlapping at least a portion of the second ring in the vertical direction.

18. The electro-static chuck of claim 16,
wherein, from a plan view, a first region of the substrate has a circular shape and a second region of the substrate has a ring shape, and
wherein a sum of a radius of the first region and a width from an inner diameter to an outer diameter of the second region is the same as a radius of the substrate or less than a radius of the substrate.

19. The electro-static chuck of claim 18, wherein the first region of the substrate and the second region of the substrate are in contact with each other.

20. The electro-static chuck of claim 16, wherein the second ring comprises at least one of quartz, silicon, silicon carbide, silicon oxide, and aluminum oxide.
